(19) United States
(12) Patent Application Publication
(10) Pub. No.: US 2003/0027058 A1
(43) Pub. Date: Feb. 6, 2003

(54) Stencil mask layout pattern data division processing system, stencil mask layout pattern data division processing method, and program read by computer to execute stencil mask layout pattern data dividing process

(76) Inventor: Kokoro Kato, Chiba-shi (JP)

Correspondence Address: ADAMS & WILKS, ATTORNEYS AND COUNSELORS AT LAW, 31st FLOOR, 50 BROADWAY, NEW YORK, NY, 10004, US

(21) Appl. No.: 10/199,783

(22) Filed: Jul. 19, 2002

(30) Foreign Application Priority Data
Aug. 1, 2001 (JP) 2001-234094

(51) Int. Cl. G06F 19/00; G06F 17/50; G03F 9/00

(52) U.S. Cl. 430/5; 716/19; 700/121; 716/20

(57) ABSTRACT

A stencil mask layout pattern data division processing system, a method thereof and a program have a scheme of optimally dividing a complicated layout pattern. Plural pieces of divided layout pattern segment data are generated by reading stencil mask layout pattern data stored in a layout pattern data memory module and dividing the layout pattern data along line segments in horizontal and vertical directions. Then, plural pieces of complementary mask data are generated by allocating the plural pieces of divided layout pattern segment data to plural pieces of complementary mask data, and are stored in a complementary mask data memory module.

### BACKGROUND OF THE INVENTION

1. Field of the Invention

The present invention relates to a stencil mask layout pattern data division processing system for a stencil mask used for manufacturing an integrated circuit, a stencil mask layout pattern data division processing method and a program read by a computer to execute a stencil mask layout pattern dividing process.

2. Description of the Related Art

A stencil mask has hitherto been developed in order to manufacture a semiconductor integrated circuit such as VLSI (very large scale integration) by utilizing an electron beam exposure etc.

A structure of the stencil mask is such that a thin plate such as a silicon plate is physically formed with holes mapped to a layout pattern that should be exposed to electron beams.

The stencil mask is thus structured to physically have the holes (openings). Hence, if the layout pattern of the semiconductor integrated circuit contains a doughnut-shaped pattern segment (a closed pattern segment) of a wire that constitutes a closed loop, the opening forms the closed loop. One single stencil mask is therefore unable to retain a center frame of the doughnut-shaped pattern segment, with the result that the layout pattern can not be structured by one single stencil mask. Hence, the doughnut-shaped pattern segment is divided into two pieces of masks, wherein there is no alternative but to effect an exposure with use of these two pieces of masks. This is a method adopted for attaining the above, wherein the layout pattern is divided and allocated to the two pieces of complementary masks. Further, the complementary mask has a weak point in terms of a mask strength, and there is a case where the layout pattern segments might be allocated to the two pieces of complementary masks.

FIGS. 12 and 13 show a typical example of dividing a layout pattern segment. If the layout pattern segment is structured by an L-shaped line, a recess-sided point (a recess corner) of connecting points at which a pair of two line segments are connected, is set as an origin, and a perpendicular is extended from this origin to an adjacent side, whereby the L-shaped pattern segment is cut off along this perpendicular and thus divided. Then, the divided pattern segments are allocated to the two complementary stencil masks. Further, as depicted in FIG. 13, even when the layout pattern segment is structured by one single line and has its length equal to or larger than a predetermined length, this layout pattern segment is divided at, e.g., the center and allocated to the two complementary masks, whereby the line length becomes equal to or smaller than the predetermined length.

FIGS. 14 and 15 are explanatory diagrams showing a layout pattern data division processing method that has hitherto been used.

Referring to FIGS. 14 and 15, a layout pattern dividing process shown in FIG. 14 involves the use of a method of simply dividing the layout pattern segment from at every recess corner in a horizontal direction (FIG. 15(a)) and a method of simply dividing the layout pattern segment from at every recess corner in a vertical direction (FIG. 15(b)).

According to the conventional dividing methods, the layout pattern segment is divided in one of the horizontal and vertical directions, and it is therefore possible to comparatively simply divide even a complicated layout pattern segment.

A requirement for dividing the layout pattern segment is that the divided/cut side should not be longer than needed and no micro pattern fragment occur after being divided in terms of an accuracy and usability, etc. of the mask when manufactured.

The conventional division processing methods present a problem in that the layout pattern segment is, as shown in FIG. 15, simply divided in one of the horizontal and vertical directions, and hence there occur the cut fragments longer than needed and the micro fragments.

### SUMMARY OF THE INVENTION

It is a primary object of the present invention, which was devised to obviate the problems described above, to provide a technology capable of executing an optimal dividing process even in the case of a complicated layout pattern segment.

To accomplish the above object, according to one aspect of the present invention, there is provided a stencil mask layout pattern data division processing system characterized by including a layout pattern data storage module stored with layout pattern data of a stencil mask, a layout pattern data reading module for reading the layout pattern data from the layout pattern data storage module, a complementary mask data storage module for storing complementary mask data, and a complementary mask data generating module for generating plural pieces of divided layout pattern segment data by dividing in a plurality of different directions the layout pattern data read by the layout pattern data reading module, generating plural pieces of complementary mask data by allocating the plural pieces of divided layout pattern segment data to plural pieces of complementary mask data, and storing the complementary mask data in the complementary mask data storage module.

The complementary mask data generating module generates the plural pieces of divided layout pattern segment data by dividing in the plurality of different directions the layout pattern data read by the layout pattern data reading module, generates the plural pieces of complementary mask data by allocating the plural pieces of divided layout pattern segment data to the plural pieces of complementary mask data, and stores the complementary mask data in the complementary mask data storage module.

Herein, the stencil mask layout pattern data division processing system may further include a divided data storage module for storing the plural pieces of divided layout pattern segment data, the complementary mask data generating module may have a divided data generating module for generating plural pieces of divided layout pattern segment data by dividing in the plurality of different directions the layout pattern data, and the complementary mask data generating module may store the divided data storage module with the plural pieces of divided layout pattern segment data generated by the divided data generating module and generates the complementary mask data by allocating the pattern data stored in the divided data storage module to the plural pieces of complementary mask data.

It may be designed such that the divided data generating module divides the layout pattern segment along the shortest perpendicular extending to an adjacent side from a recess corner of the layout pattern data.

It may be designed such that the divided data generating module, if a plurality of shortest perpendiculars exist, divides the layout pattern segment to form the longest minor side among a plurality of sides extended between feet of the perpendiculars and a plurality of apexes sandwiching the feet interposed therebetween.

It may be designed such that the divided data generating module, if a plurality of longest minor sides exist, divides the layout pattern segment to form the longest major side among a plurality of sides extended between feet of the perpendiculars and a plurality of apexes sandwiching the feet interposed therebetween.

It may be designed such that the divided data generating module, if a plurality of shortest perpendiculars exist, divides the layout pattern segment to form the longest major side among a plurality of sides extended between feet of the perpendiculars and a plurality of apexes sandwiching the feet interposed therebetween.

It may be designed such that the divided data generating module, if a plurality of longest major sides exist, divides the layout pattern segment to form the longest minor side among a plurality of sides extended between feet of the perpendiculars and a plurality of apexes sandwiching the feet interposed therebetween.

It may be designed such that the divided data generating module, if a length of a side of the pattern segment after being divided will be equal to or smaller than a predetermined length, does not divide the pattern segment.

It may be designed such that the divided data generating module, if a length of the layout pattern segment is equal to or larger than a predetermined length, divides the pattern segment at a predetermined position irrespective of whether there is a recess corner or not.

It may be designed such that the divided data generating module, if a foot of the perpendicular is positioned on the already cut-off side, does not cut the pattern segment along the perpendicular.

It may be designed such that the divided data generating module, if two pieces of layout pattern segments adjacent to each other belong to the same complementary mask, subdivides one layout pattern segment into a plurality of layout pattern segments, and the complementary mask data generating module allocates the subdivided layout pattern segments such that the subdivided layout pattern segment, adjacent to the other layout pattern segment, among the plurality of subdivided layout pattern segments belongs to other complementary mask.

It may be designed such that a dividing condition storage module which stores dividing conditions beforehand may also be provided, and that the divided data generating module generates the plural pieces of divided layout pattern segment data by dividing in the plurality of different directions the layout pattern data to meet dividing conditions stored in the dividing condition storage module.

It may be designed such that there may be provided a dividing condition setting module for setting the dividing conditions in the dividing condition storage module.

Further, according to the present invention, there is provided a stencil mask layout pattern data division processing method characterized in that a layout pattern data reading module reads layout pattern data from a layout pattern data storage module stored with the layout pattern data of a stencil mask, a complementary mask data generating module generates plural pieces of divided layout pattern segment data by dividing in a plurality of different directions the layout pattern data read by the layout pattern data reading module, generates plural pieces of complementary mask data by allocating the plural pieces of divided layout pattern segment data to plural pieces of complementary mask data, and stores the complementary mask data in the complementary mask data storage module.

The complementary mask data generating module generates the plural pieces of divided layout pattern segment data by dividing in the plurality of different directions the layout pattern data read by the layout pattern data reading module, generates the plural pieces of complementary mask data by allocating the plural pieces of divided layout pattern segment data to the plural pieces of complementary mask data, and stores the complementary mask data in the complementary mask data storage module.

Herein, an arrangement may be made such that the complementary mask data generating module has a function as a divided data generating module for generating plural pieces of divided layout pattern segment data by dividing in a plurality of different directions the layout pattern data, and the complementary mask data generating module stores a divided data storage module with the plural pieces of divided layout pattern segment data generated by the divided data generating module, and generates the complementary mask data by allocating the pattern data stored in the divided data storage module to plural pieces of complementary mask data.

An arrangement may be made such that the divided data generating module divides the layout pattern segment along the shortest perpendicular extending to an adjacent side from a recess corner of the layout pattern data.

An arrangement may be made such that the divided data generating module, if a plurality of shortest perpendiculars exist, divides the layout pattern segment to form the longest minor side among a plurality of sides extended between feet of the perpendiculars and a plurality of apexes sandwiching the feet interposed therebetween.

An arrangement may be made such that the divided data generating module, if a plurality of longest minor sides exist, divides the layout pattern segment to form the longest major side among a plurality of sides extended between feet of the perpendiculars and a plurality of apexes sandwiching the feet interposed therebetween.

An arrangement may be made such that the divided data generating module, if a plurality of shortest perpendiculars exist, divides the layout pattern segment to form the longest major side among a plurality of sides extended between feet of the perpendiculars and a plurality of apexes sandwiching the feet interposed therebetween.

An arrangement may be made such that the divided data generating module, if a plurality of longest major sides exist, divides the layout pattern segment to form the longest minor side among a plurality of sides extended between feet of the perpendiculars and a plurality of apexes sandwiching the feet interposed therebetween.

An arrangement may be made such that the divided data generating module, if a length of a side of the pattern segment after being divided will be equal to or smaller than a predetermined length, does not divide the pattern segment.

An arrangement may be made such that the divided data generating module, if a length of the layout pattern segment is equal to or larger than a predetermined length, divides the pattern segment at a predetermined position irrespective of whether there is a recess corner or not.

An arrangement may be made such that the divided data generating module, if a foot of the perpendicular is positioned on the already cut-off side, does not cut the pattern segment along the perpendicular.

An arrangement may be made such that the divided data generating module, if two pieces of layout pattern segments adjacent to each other belong to the same complementary mask, subdivides one layout pattern segment into a plurality of layout pattern segments, and the complementary mask data generating module allocates the subdivided layout pattern segments such that the subdivided layout pattern segment, adjacent to the other layout pattern segment, among the plurality of subdivided layout pattern segments belongs to other complementary mask.

An arrangement may be made such that the divided data generating module generates the plural pieces of divided layout pattern segment data by dividing in the plurality of different directions the layout pattern data to meet dividing conditions stored in the dividing condition storage module.

An arrangement may also be made such that the dividing condition setting module sets the dividing conditions in the dividing condition storage module.

Further, according to the present invention, there is provided a program characterized in that a computer reads and executes the program, thereby functioning as a layout pattern data reading module for reading layout pattern data of a stencil mask from a layout pattern data storage module stored with the layout pattern data, and the complementary mask data generating module for generating plural pieces of divided layout pattern segment data by dividing in a plurality of different directions the layout pattern data read by the layout pattern data reading module, generating plural pieces of complementary mask data by allocating the plural pieces of divided layout pattern segment data to plural pieces of complementary mask data, and storing the complementary mask data in the complementary mask data storage module.

The computer executes the program of the present invention, thereby functioning as the layout pattern data reading module for reading the layout pattern data of the stencil mask from the layout pattern data storage module stored with the layout pattern data, and as the complementary mask data generating module for generating the plural pieces of divided layout pattern segment data by dividing in the plurality of different directions the layout pattern data read by the layout pattern data reading module, generating the plural pieces of complementary mask data by allocating the plural pieces of divided layout pattern segment data to the plural pieces of complementary mask data, and storing the complementary mask data in the complementary mask data storage module.

Herein, the program may be designed for making the computer function so that the complementary mask data generating module has a function as a divided data generating module for generating plural pieces of divided layout pattern segment data by dividing in a plurality of different directions the layout pattern data, and the complementary mask data generating module stores a divided data storage module with the plural pieces of divided layout pattern segment data generated by the divided data generating module, and generates the complementary mask data by allocating the pattern data stored in the divided data storage module to plural pieces of complementary mask data.

Further, the program may be designed for making the computer function so that the divided data generating module divides the layout pattern segment along the shortest perpendicular extending to an adjacent side from a recess corner of the layout pattern data.

Moreover, the program may be designed for making the computer function so that the divided data generating module, if a plurality of shortest perpendiculars exist, divides the layout pattern segment to form the longest minor side among a plurality of sides extended between feet of the perpendiculars and a plurality of apexes sandwiching the feet interposed therebetween.

Moreover, the program may be designed for making the computer function so that the divided data generating module, if a plurality of longest minor sides exist, divides the layout pattern segment to form the longest major side among a plurality of sides extended between feet of the perpendiculars and a plurality of apexes sandwiching the feet interposed therebetween.

Moreover, the program may be designed for making the computer function so that the divided data generating module, if a plurality of shortest perpendiculars exist, divides the layout pattern segment to form the longest major side among a plurality of sides extended between feet of the perpendiculars and a plurality of apexes sandwiching the feet interposed therebetween.

Moreover, the program may be designed for making the computer function so that the divided data generating module, if a plurality of longest major sides exist, divides the layout pattern segment to form the longest minor side among a plurality of sides extended between feet of the perpendiculars and a plurality of apexes sandwiching the feet interposed therebetween.

The program may be designed for making the computer function so that the divided data generating module, if a length of a side of the pattern segment after being divided will be equal to or smaller than a predetermined length, does not divide the pattern segment.

The program may be designed for making the computer function so that the divided data generating module, if a length of the layout pattern segment is equal to or larger than a predetermined length, divides the pattern segment at a predetermined position irrespective of whether there is a recess corner or not.

The program may be designed for making the computer function so that the divided data generating module, if a foot of the perpendicular is positioned on the already cut-off side, does not cut the pattern segment along the perpendicular.

The program may be designed for making the computer function so that the divided data generating module, if two pieces of layout pattern segments adjacent to each other belong to the same complementary mask, subdivides one layout pattern segment into a plurality of layout patterns, and so that the complementary mask data generating module allocates the subdivided layout pattern segments such that the subdivided layout pattern segment, adjacent to the other layout pattern segment, among the plurality of subdivided layout pattern segments belongs to other complementary mask.

The program may be designed for making the computer function so that the divided data generating module generates the plural pieces of divided layout pattern segment data by dividing in the plurality of different directions the layout pattern data to meet dividing conditions stored beforehand in the dividing condition storage module.

The program may be designed for making the computer function also as a dividing condition setting module for setting the dividing conditions in the dividing condition storage module.

### BRIEF DESCRIPTION OF THE DRAWINGS

In the accompanying drawings:

FIG. 1 is a block diagram showing a stencil mask layout pattern data division processing system in accordance with an embodiment of the present invention;

FIG. 2 is a flowchart showing processes in accordance with the embodiment of the present invention;

FIG. 3 is a flowchart showing processes in accordance with the embodiment of the present invention;

FIG. 4 is an explanatory diagram showing a process of dividing a layout pattern segment in the embodiment of the present invention;

FIG. 5 is an explanatory diagram showing the process of dividing the layout pattern segment in the embodiment of the present invention;

FIG. 6 is an explanatory diagram showing the process of dividing the layout pattern segment in the embodiment of the present invention;

FIG. 7 is an explanatory diagram showing the process of dividing the layout pattern segment in the embodiment of the present invention;

FIG. 8 is an explanatory diagram showing the process of dividing the layout pattern segment in the embodiment of the present invention;

FIG. 9 is an explanatory diagram showing the process of dividing the layout pattern segment in the embodiment of the present invention;

FIG. 10 is an explanatory diagram showing the process of dividing the layout pattern segment in the embodiment of the present invention;

FIG. 11 is an explanatory diagram showing the process of dividing the layout pattern segment in the embodiment of the present invention;

FIG. 12 is an explanatory diagram showing the process of dividing a general layout pattern segment;

FIG. 13 is an explanatory diagram showing the process of dividing a general layout pattern segment;

FIG. 14 is an explanatory diagram showing the process of dividing a layout pattern segment in prior art; and

FIG. 15 is an explanatory diagram showing the process of dividing a layout pattern segment in prior art.

### DESCRIPTION OF THE PREFERRED EMBODIMENT

With reference to the accompanying drawings, the description in accordance with an embodiment of the present invention will hereinafter be made on a stencil mask layout pattern data division processing system, a stencil mask layout pattern data division processing method, and a program read by a computer to execute a stencil mask layout pattern data dividing process.

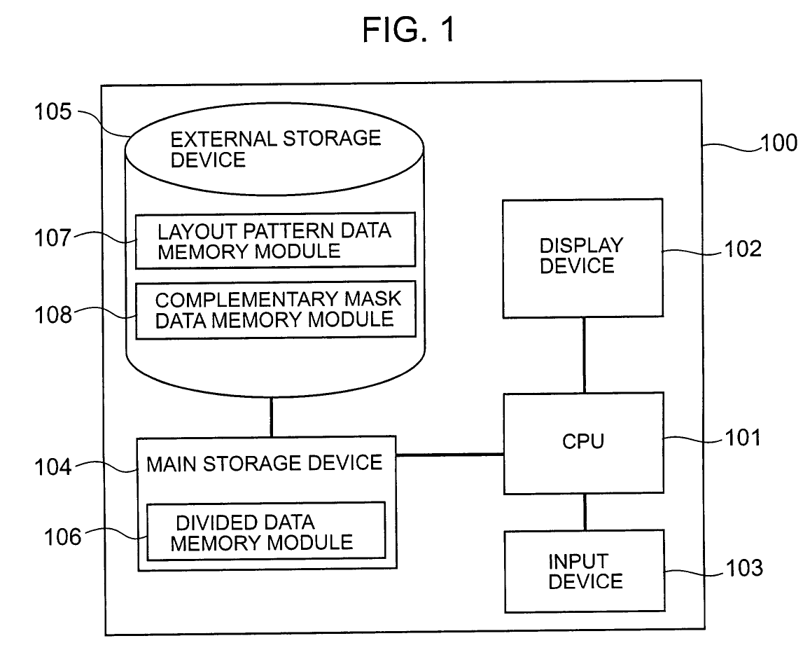

FIG. 1 is a block diagram showing a stencil mask layout pattern data division processing system in accordance with the embodiment of the present invention.

Referring to FIG. 1, a computer-based layout pattern data division processing system 100 includes a central processing unit (CPU) 101 defined as a processing unit for executing a variety of arithmetic processes, a display device 102 defined as a display unit constructed of a CRT etc, and an input device 103 defined as an operation unit and a dividing condition setting unit which are constructed of a keyboard, a mouse etc. This system 100 further includes an external storage device 105 constructed of a magnetic disk etc stored with a program executed by the CPU 101 and layout pattern data etc of an integrated circuit, and a main storage device 104 cached with the above program, at least a part of the layout pattern data and pieces of information in process of being processed.

The external storage device 105 has a layout pattern data memory module 107 defined as a layout pattern data storage module, and a complementary mask data memory module 108 defined as a complementary mask data storage module.

The layout pattern data memory module 107 is stored beforehand with the layout pattern data of the integrated circuit. Further, the complementary mask data memory module 108 executes a process of dividing the layout pattern data, and stores complementary mask data obtained by allocating the divided layout pattern data to two pieces of complementary stencil masks.

The main storage device 104 has a divided data memory module 106 for caching divided pieces of layout patterns into which the above layout pattern is divided, and is structured to form a virtual memory space. The main storage device 104 executes a process by utilizing this virtual memory space when the layout pattern data division processing system 100 executes the process of dividing the layout pattern with use of the layout pattern data described above and also a process of generating the complementary mask. Note that the external storage device 105 and the main storage device 104 constitute a storage system.

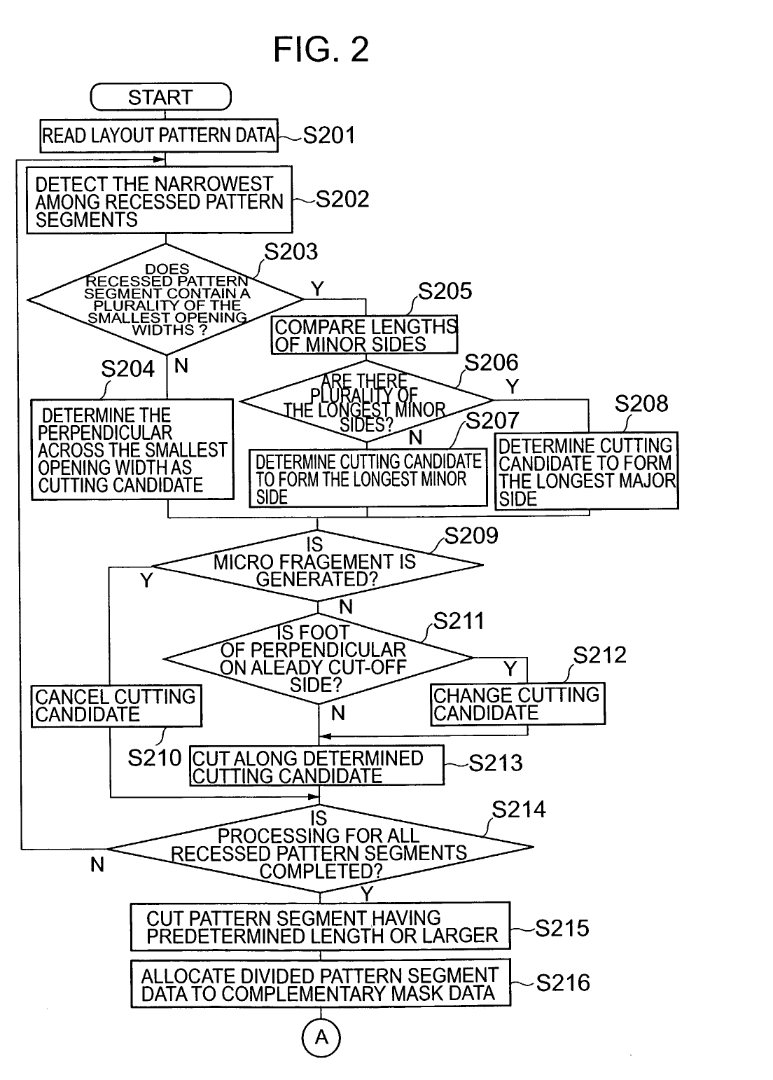

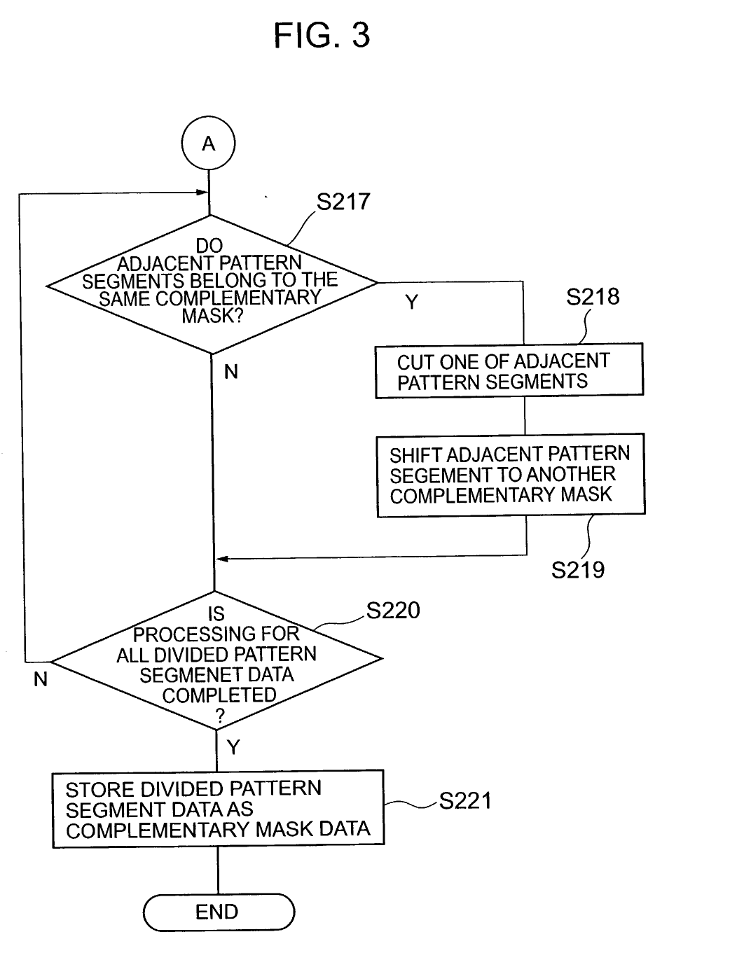

FIGS. 2 and 3 are flowcharts showing processes of the stencil mask layout pattern data division processing system 100 according to the embodiment of the present invention. A program installed into the external storage device 105 is stored in the main storage device 104 and processed by the CPU 101, thereby executing a series of procedures (algorithm) shown in these flowcharts.

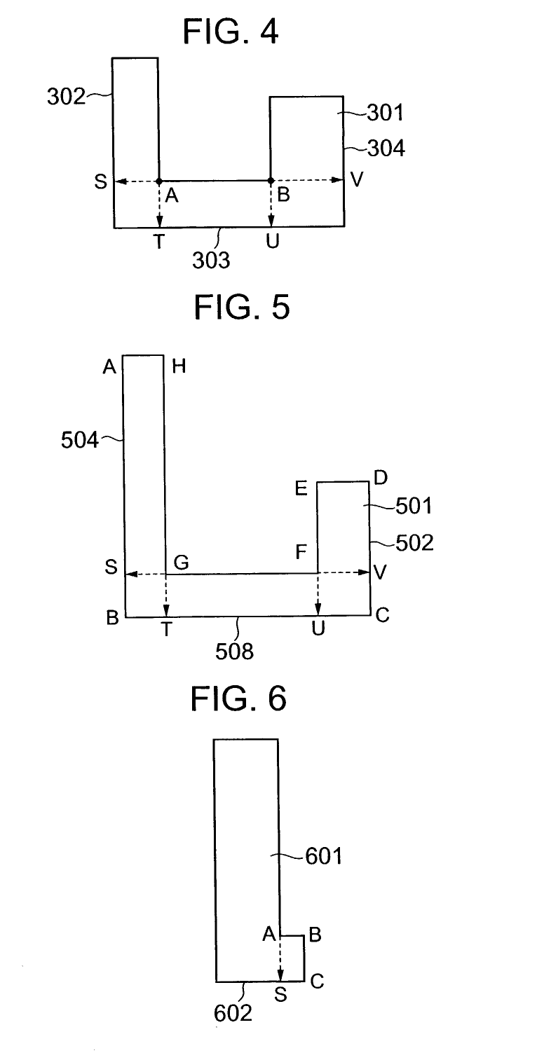

FIGS. 4 through 11 are explanatory diagrams showing the processes in the embodiment of the present invention as well as illustrating layout patterns of the semiconductor integrated circuit. Note that the layout patterns shown in FIGS. 4 through 11 may also be displayed on the display device 102.

The stencil mask layout pattern data division processing system, the stencil mask layout pattern data division processing method, and the program read by the computer to execute the stencil mask layout pattern data dividing process in accordance with the embodiment of the present invention, will hereinafter be described with reference to FIGS. 1 through 11.

In response to an operation on the input device 103, to start with, the layout pattern data of the semiconductor integrated circuit is read from the layout pattern data memory module 107 (step S201) . Herein, step S201 corresponds to a layout pattern data reading process.

Next, the narrowest among recessed pattern segments contained in the readout layout pattern data is detected (step S202). The recessed pattern segment is herein structured by connecting points of a plurality of sides that form an opening of the layout pattern, and implies the recessed area of the opening.

In step S202, each of recess corners (points) being defined as an origin, perpendiculars are extended to adjacent sides from the origins, and a pattern segment containing the shortest perpendicular (which is, in other words, the pattern segment containing the smallest opening width) is detected. The perpendicular may be extended, if possible of forming the perpendicular, in either of horizontal and vertical directions without being limited to only one of the horizontal and vertical directions.

Next, it is judged whether the recessed pattern segment contains a plurality of the smallest opening widths, in other words, a plurality of the shortest perpendiculars (step S203). When judging in step S203 that there exits only the single smallest opening width, the perpendicular extended across the smallest opening width concerned is determined as a candidate for cutting (step S204), and the operation proceeds to step S209.

Given herein is an explanation of a process of determining the candidate for cutting in steps S203 and S204. The process of determining the candidate for cutting with respect to the layout pattern in steps S203, S204 basically involves extending at first the perpendiculars to the adjacent sides from the recess corners (points) of the layout pattern and setting the shortest among the perpendiculars as the candidate for cutting.

Referring to FIG. 4, an opening 301 takes substantially a C-shape, wherein points A and B are defined as recess corners. From the recess corner A, a perpendicular AS is extended in an X-direction (the horizontal direction) to a point S on an adjacent side 302, and a perpendicular AT is extended in a Y-direction (the vertical direction) to a point T on an adjacent side 303. Similarly, from the recess corner B, a perpendicular BU is extended in the Y-direction to a point U existing on the adjacent side 303, and a perpendicular BV is extended in the X-direction to a point V on an adjacent side 304. The shortest among the perpendiculars AS, AT, BU and BV is the perpendicular AS, i.e., the perpendicular AS has the smallest width in the opening 301 and is therefore determined as a candidate for cutting. Further, if the layout pattern is divided in half along the perpendicular AS, with respect to two divided segments of the layout pattern, the candidate for cutting is likewise determined, and the dividing process is carried out, thus executing the processing with respect to all the recessed pattern segments (step S214 that will be explained later on).

On the other hand, when judging in step S203 that there exist a plurality of the smallest opening widths, with respect to the area having the minimum opening width, a length of a line segment (a minor side) having the shorter of distances between each of two apexes and a foot of one perpendicular extended to one adjacent side from the recess corner and interposed between these two apexes, is compared with a length of a line segment having the shorter of distances between each of two apexes and a foot of another perpendicular extended to another adjacent side from the same recess corner and interposed between these two apexes (step S205).

Next, it is judged whether there exist a plurality of the longest minor sides (step S206). If there exists only the single longest minor side, the perpendicular from which this minor side is formed is determined as a candidate for cutting (step S207), and the operation proceeds to step S209.

When judging in step S206 that there exist the plurality of the longest minor sides, with respect to the maximum minor side, the maximum among lengths of line segments (major sides) each having the longer of distances between each of two apexes and a foot of one perpendicular extended to one adjacent side from the recess corner and interposed between these two apexes, is detected, and the perpendicular from which this maximum major side is formed is determined as a candidate for cutting (step S208). Then, the operation proceeds to step S209.

Herein, in the case of judging in step S203 that there exist the plurality of the smallest opening widths, the processes in steps S205 through S208 will specifically be explained referring to FIG. 5.

The layout pattern cutting candidate determining process in steps S205 through S208 is basically that the distances between the feet of the perpendiculars extended to the adjacent sides from the plurality of recess corners (points) and the respective two apexes sandwiching the feet interposed therebetween, are calculated, and the perpendicular exhibiting the most allowable length is determined as the candidate for cutting.

For instance, to begin with, the lengths of the minor sides among the line segments extending from the feet f the perpendiculars as the candidates for cutting and the respective two apexes sandwiching the feet interposed therebetween, are compared with each other, and such a perpendicular as to generate a layout pattern having the longest minor side is determined as the candidate for cutting. If the plurality of the longest minor sides exist, with respect to the maximum minor side, a length of a major side of the line segments formed between each of two apexes and a foot of one perpendicular extended to one adjacent side from the recess corner and interposed between these two apexes, is compared with a length of a major side of the line segments formed between each of two apexes and a foot of another perpendicular extended to another adjacent side from the same recess corner and interposed between these two apexes, whereby such a perpendicular as to generate a layout pattern having the longest major side is determined as a candidate for cutting.

An example of the process given above will be specifically described with reference to FIG. 5. Referring to FIG. 5, an opening 501 takes substantially a C-shape, wherein points F and G are defined as recess corners. From the recess corner F, a perpendicular FV is extended in the X-direction (the horizontal direction) to a point V on an adjacent side 502, and a perpendicular FU is extended in the Y-direction (the vertical direction) to a point U on an adjacent side 503. Similarly, from the recess corner G, a perpendicular GT is extended in the Y-direction to a point T on the adjacent side 503, and a perpendicular GS is extended in the X-direction to a point S on an adjacent side 504.

Then, at first, the shortest among the perpendiculars GS, GT, FU and FV is determined as a candidate for cutting (step S202). If the lengths of the perpendiculars GS, GT, FU, FV are all the same, it is judged in step S203 that a plurality of the smallest opening widths exist, the operation proceeds to step S205, wherein lengths of the respective minor sides are compared with each other. Herein, there are formed four minor sides SB, TB, UC and VC. Therefore, lengths of the respective minor sides SB, TB, UC, VC are compared with each other, and, if it proves that the single longest minor side exists, a perpendicular from which the longest minor side is formed is determined as a candidate for cutting (steps s206, S207). If the lengths of the respective minor sides SB, TB, UC, VC are all the same, it is judged in step S206 that a plurality of the longest minor sides exist, and a perpendicular from which the longest among the major sides SA, TC, UB, VD is formed is determined as a candidate for cutting (step S208). The example in FIG. 5 shows that the longest major side is SA, and hence the perpendicular GS is determined as the candidate for cutting.

Next, in the case of dividing the layout pattern data by cutting along the perpendicular as the cutting candidate, it is judged whether a micro fragment containing a side having a predetermined length or smaller is generated or not (step S209). FIG. 6 is an explanatory diagram showing a process of determining a cutting candidate in step S209. Referring to FIG. 6, an opening 601 is formed in such a shape that a small rectangular segment is integral with a large rectangular segment, wherein a point A is defined as a recess corner. A perpendicular AS is extended in the Y-direction to a point S on an adjacent side 602 from the recess corner A. Accordingly, if cut along the perpendicular AS, a small square ASCB is formed. In this case, if the length of any one of a side AB and a side SC is equal to or smaller than a predetermined value, it follows that the micro fragment is generated. Such being the case, if the length of at least one of the sides AB and SC is equal to or smaller than the predetermined value, the perpendicular AS is not set as the cutting candidate. It is judged in step S209 whether the cutting candidates determined in steps S204, S207, S208 are set as effective cutting candidates. This scheme makes it possible to prevent the micro fragment of the pattern from occurring when cutting along the perpendicular in the layout pattern.

When judging in step S209 that the micro fragment is generated, the cutting candidate is canceled (step S210), and the operation diverts to step S214. Whereas if it is judged that the micro fragment is not generated, it is judged whether the foot of the perpendicular as the cutting candidate is positioned on the side that has already been cut off (step S211).

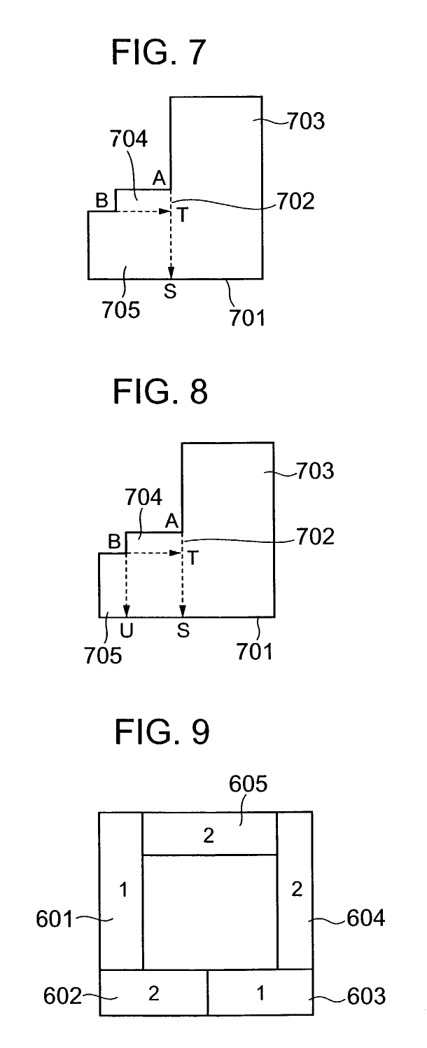

FIGS. 7 and 8 are explanatory diagrams each showing the process of determining the cutting candidate in step S211. If three or more cut-off layout pattern segments are adjacent to each other and belong to the same complementary mask, there arises a problem in terms of manufacturing the mask. Namely, as illustrated in FIG. 7, at first a perpendicular AS is extended from a recess corner (point) A to a point S on an adjacent side 701 and then determined as a cutting candidate. Thereafter, a perpendicular BT is extended from a recess corner (point) B to a point T on an adjacent side 702 and then determined as a second cutting candidate. In this case, three layout pattern segments 703, 704, 705 are adjacent to each other and can be allocated to two pieces of complementary masks 1, 2.

Then, with respect to the layout pattern segment having already undergone the cutting process, if the foot of the perpendicular is positioned on the existing cut-off side, a scheme is that this perpendicular is not set as the cutting candidate. This process eliminates a possibility that three or more pattern segments are adjacent to each other. Thus, it is assured that the layout pattern segments are allocated to the complementary masks.

To describe this in greater detail with reference to FIG. 8, in step S211, when the next cutting candidate is determined after the layout pattern segment is cut along the line segment AS, a foot T of the perpendicular extending from the recess corner B is positioned on the existing cut-off side AS and is therefore not set as a cutting-candidate point. Instead, in step S212, the perpendicular BU extended in the Y-direction to a point U on the adjacent side 702 from the recess corner B is changed into a cutting candidate, the layout pattern segment is divided by cutting along the thus determined cutting candidate perpendicular BU, and plural pieces of layout pattern segment data obtained by the dividing process described above are stored in the divided data memory module 106 (step S213).

The processes described above are executed with respect to all the recessed pattern segments including the layout pattern segment data (divided pattern segment data) after being divided, and divided layout pattern segment data obtained are stored in the divided data memory module 106 (step S214).

Next, if the plural pieces of divided pattern segment data obtained contain a length equal to or larger than a predetermined length, the divided pattern segment data is subdivided by further cutting, and with this scheme, the divided pattern segment data do not contain the length equal to or larger than the predetermined length (step S215). The divided pattern segment data obtained by the process described above are also stored in the divided data memory module 106.

Next, all the divided pattern segment data obtained are allocated to two sheets of complementary stencils (step S216).

Subsequently, it is judged whether the adjacent divided pattern segments belong to the same complementary mask (step S217 in FIG. 3).

For example, as shown in FIG. 9, in the case of executing a process of dividing a closed pattern, if simply divided, there may occur a case where the adjacent layout pattern segments belong to the same complementary mask, and this is a problem in terms of manufacturing the mask. Namely, referring to FIG. 9, a whole opening taking a closed pattern is divided into a plurality of openings 601 through 605. These openings 601 through 605 are allocated so that the openings 601, 603 belong to a first complementary mask 1, and the openings 602, 604, 605 belong to a second complementary mask 2. In this case, the openings 604, 605 belonging to the same complementary mask are adjacent to each other. Therefore, the openings 604, 605 are not separated in the second complementary mask 2, resulting in a problem in terms of manufacturing the mask.

Steps S217 through S220 show a procedure for preventing this problem. To be specific, when judging in step S217 that the adjacent pattern segments belong to the same complementary mask, one of the adjacent layout pattern segments is cut off (step S218), and one, adjacent to the other layout pattern segment described above, of two pieces of cut-off layout pattern segments is shifted to the other complementary mask (step S219).

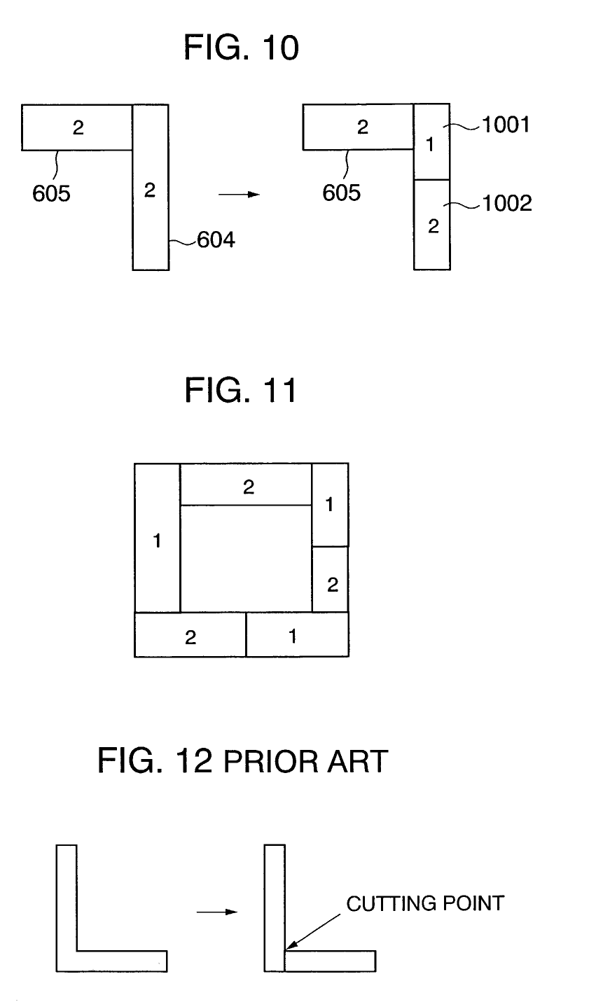

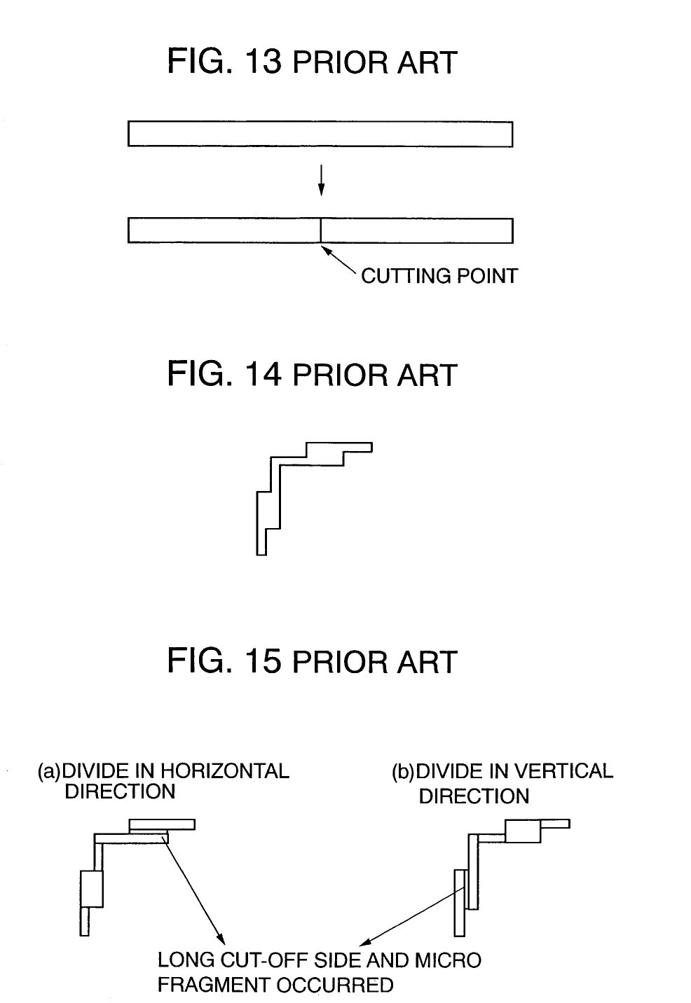

Namely, as depicted in FIGS. 10 and 11, the pattern segment 604 belonging to the stencil mask 2 is divided in half in the X-axis direction, a pattern segment 1001, adjacent to the layout pattern segment 605, of two pieces of divided layout pattern segments 1001, 1002 is so changed as to belong to the mask 1. Owing to this scheme, as illustrated in FIG. 11, it is possible to prevent an occurrence of such an undesirable design that the pattern segments adjacent to each other belong to the same complementary mask, whereby the layout pattern is properly divided and the divided pattern segments are also properly allocated. The processes explained above are executed with respect to all the layout pattern segments, and the layout pattern data obtained are all stored in the divided data memory module 106 (step S220).

The plural pieces of divided layout pattern segment data stored in the divided data memory module 106, are allocated to the plurality of complementary masks, and the thus obtained complementary mask data are stored in the complementary mask data memory module 108, thereby finishing the processing (step S221).

Note that steps S202 through S221 in the processes described above correspond to a complementary mask data generating procedure, and steps S202 through S215 and S217 through S220 in the processes described above correspond to a divided data generating procedure.

As discussed above, the stencil mask layout pattern data division processing system in accordance with the embodiment of the present invention includes the layout pattern data storage module stored with the layout pattern data of the stencil mask, the layout pattern data reading module for reading the layout pattern data from the layout pattern data storage module, the complementary mask data storage module for storing the complementary mask data, and the complementary mask data generating module for generating the plural pieces of divided layout pattern segment data by dividing in the plurality of different directions the layout pattern data read by the layout pattern data reading module, generating the plural pieces of complementary mask data by allocating the plural pieces of divided layout pattern segment data to the plural pieces of complementary mask data, and storing the complementary mask data in the complementary mask data storage module. Accordingly, even in the case of the complicated layout pattern, the optimal dividing process can be executed.

Further, according to the stencil mask layout pattern data division processing method in accordance with the embodiment of the present invention, in particular, the layout pattern data reading module reads the layout pattern data from the layout pattern data storage module stored with the layout pattern data of the stencil mask, the complementary mask data generating module generates the plural pieces of divided layout pattern segment data by dividing in the plurality of different directions the layout pattern data read by the layout pattern data reading module, generates the plural pieces of complementary mask data by allocating the plural pieces of divided layout pattern segment data to the plural pieces of complementary mask data, and stores the complementary mask data in the complementary mask data storage module. Hence, even in the case of the complicated layout pattern, the optimal dividing process can be executed.

Further, the computer reads and executes the program of the present invention, thereby functioning as the layout pattern data reading module for reading layout pattern data of a stencil mask from a layout pattern data storage module stored with the layout pattern data, and the complementary mask data generating module for generating the plural pieces of divided layout pattern segment data by dividing in a plurality of different directions the layout pattern data read by the layout pattern data reading module, generating plural pieces of complementary mask data by allocating the plural pieces of divided layout pattern segment data to plural pieces of complementary mask data, and storing the complementary mask data in the complementary mask data storage module. Accordingly, the computer executes this program, whereby the optimal dividing process can be implemented even in the case of the complicated layout pattern.

Note that the order of the multiple processes shown in FIGS. 2 and 3 may be changed as the necessity arises. For example, when judging in step S206 that there exist the plurality of shortest perpendiculars, a scheme is that the layout pattern segment may be divided to have the longest major side among a plurality of sides extended between the feet of the respective perpendiculars and the plurality of apexes sandwiching the feet interposed therebetween. Further, if there exist the plurality of longest major sides, a scheme is that the layout pattern segment may be divided to have the longest minor side among a plurality of sides extended between the feet of the respective perpendiculars and the plurality of apexes sandwiching the feet interposed therebetween.

Moreover, the process of judging whether the micro fragment is generated (step S209) and the like may be executed a plurality of times such as implementing this judging process each time any one of the processes is carried out.

Further, there may be taken such a structure that the external storage device 105 is provided inside with a dividing condition storage module stored beforehand with layout pattern dividing conditions, and the divided data generating module generates the plural pieces of divided layout pattern segment data by dividing in the plurality of different directions the layout pattern data so as to meet the dividing conditions stored in the dividing condition storage module. In this case, the dividing conditions may be inputted by operating the input device 103 and stored in the dividing condition storage module.

The stencil mask layout pattern data division processing system according to the present invention is capable of executing the optimal dividing process even in the case of the complicated layout pattern.

Further, the stencil mask layout pattern data division processing method according to the present invention is capable of executing the optimal dividing process even in the case of the complicated layout pattern.

Still further, the program according to the present invention is capable of making the computer to execute the optimal dividing process even in the case of the complicated layout pattern.

What is claimed is:

1. A stencil mask layout pattern data division processing system comprising:
a layout pattern data storage module stored with layout pattern data of a stencil mask;
a layout pattern data reading module for reading the layout pattern data from the layout pattern data storage module;
a complementary mask data storage module for storing complementary mask data; and
a complementary mask data generating module for generating plural pieces of divided layout pattern segment data by dividing in a plurality of different directions the layout pattern data read by the layout pattern data reading module, generating plural pieces of complementary mask data by allocating the plural pieces of divided layout pattern segment data to plural pieces of complementary mask data, and storing the complementary mask data in the complementary mask data storage module.

2. A stencil mask layout pattern data division processing system according to claim 1, further comprising: a divided data storage module for storing the plural pieces of divided layout pattern segment data; and the complementary mask data generating module comprising a divided data generating module for generating plural pieces of divided layout pattern segment data by dividing in the plurality of different directions the layout pattern data, wherein
the complementary mask data generating module stores the divided data storage module with the plural pieces of divided layout pattern segment data generated by the divided data generating module and generates the complementary mask data by allocating the pattern data stored in the divided data storage module to the plural pieces of complementary mask data.

3. A stencil mask layout pattern data division processing system according to claim 2, wherein the divided data generating module divides the layout pattern segment along the shortest perpendicular extending to an adjacent side from a recess corner of the layout pattern data.

4. A stencil mask layout pattern data division processing system according to claim 3, wherein the divided data generating module, if a plurality of shortest perpendiculars exist, divides the layout pattern segment to form the longest minor side among a plurality of sides extended between feet of the perpendiculars and a plurality of apexes sandwiching the feet interposed therebetween.

5. A stencil mask layout pattern data division processing system according to claim 4, wherein the divided data generating module, if a plurality of longest minor sides exist, divides the layout pattern segment to form the longest major side among a plurality of sides extended between feet of the perpendiculars and a plurality of apexes sandwiching the feet interposed therebetween.

6. A stencil mask layout pattern data division processing system according to claim 3, wherein the divided data generating module, if a plurality of shortest perpendiculars exist, divides the layout pattern segment to form the longest major side among a plurality of sides extended between feet of the perpendiculars and a plurality of apexes sandwiching the feet interposed therebetween.

7. A stencil mask layout pattern data division processing system according to claim 6, wherein the divided data generating module, if a plurality of longest major sides exist, divides the layout pattern segment to form the longest minor side among a plurality of sides extended between feet of the perpendiculars and a plurality of apexes sandwiching the feet interposed therebetween.

8. A stencil mask layout pattern data division processing system according to claim 2, wherein the divided data generating module, if a length of a side of the pattern segment after being divided will be equal to or smaller than a predetermined length, does not divide the pattern segment.

9. A stencil mask layout pattern data division processing system according to claim 2, wherein the divided data generating module, if a length of the layout pattern segment is equal to or larger than a predetermined length, divides the pattern segment at a predetermined position irrespective of whether there is a recess corner or not.

10. A stencil mask layout pattern data division processing system according to claim 2, wherein the divided data generating module, if a foot of the perpendicular is positioned on the already cut-off side, does not cut the pattern segment along the perpendicular.

11. A stencil mask layout pattern data division processing system according to claim 2, wherein the divided data generating module, if two pieces of layout pattern segments adjacent to each other belong to the same complementary mask, subdivides one layout pattern segment into a plurality of layout pattern segments, and the complementary mask data generating module allocates the subdivided layout pattern segments such that the subdivided layout pattern segment, adjacent to the other layout pattern segment, among the plurality of subdivided layout pattern segments belongs to other complementary mask.

12. A stencil mask layout pattern data division processing system according to claim 2, further comprising a dividing condition storage module which stores dividing conditions beforehand, wherein
the divided data generating module generates the plural pieces of divided layout pattern segment data by dividing in the plurality of different directions the layout pattern data to meet dividing conditions stored in the dividing condition storage module.

13. A stencil mask layout pattern data division processing system according to claim 12, comprising a dividing condition setting module for setting the dividing conditions in the dividing condition storage module.

14. A stencil mask layout pattern data division processing method, wherein:
the layout pattern data reading module reads layout pattern data of a stencil mask from a layout pattern data storage module stored with the layout pattern data; and
the complementary mask data generating module generates plural pieces of divided layout pattern segment data by dividing in a plurality of different directions the layout pattern data read by the layout pattern data reading module, generates plural pieces of complementary mask data by allocating the plural pieces of divided layout pattern segment data to plural pieces of complementary mask data, and stores the complementary mask data in the complementary mask data storage module.

15. A stencil mask layout pattern data division processing method according to claim 14, wherein:
the complementary mask data generating module has a function as a divided data generating module for generating plural pieces of divided layout pattern segment data by dividing in a plurality of different directions the layout pattern data; and
the complementary mask data generating module stores a divided data storage module with the plural pieces of divided layout pattern segment data generated by the divided data generating module, and generates the complementary mask data by allocating the pattern data stored in the divided data storage module to plural pieces of complementary mask data.

16. A stencil mask layout pattern data division processing method according to claim 15, wherein the divided data generating module divides the layout pattern segment along the shortest perpendicular extending to an adjacent side from a recess corner of the layout pattern data.

17. A stencil mask layout pattern data division processing method according to claim 16, wherein the divided data generating module, if a plurality of shortest perpendiculars exist, divides the layout pattern segment to form the longest minor side among a plurality of sides extended between feet of the perpendiculars and a plurality of apexes sandwiching the feet interposed therebetween.

18. A stencil mask layout pattern data division processing method according to claim 17, wherein the divided data generating module, if a plurality of longest minor sides exist, divides the layout pattern segment to form the longest major side among a plurality of sides extended between feet of the perpendiculars and a plurality of apexes sandwiching the feet interposed therebetween.

19. A stencil mask layout pattern data division processing method according to claim 16, wherein the divided data generating module, if a plurality of shortest perpendiculars exist, divides the layout pattern segment to form the longest major side among a plurality of sides extended between feet of the perpendiculars and a plurality of apexes sandwiching the feet interposed therebetween.

20. A stencil mask layout pattern data division processing method according to claim 19, wherein the divided data generating module, if a plurality of longest major sides exist, divides the layout pattern segment to form the longest minor side among a plurality of sides extended between feet of the perpendiculars and a plurality of apexes sandwiching the feet interposed therebetween.

21. A stencil mask layout pattern data division processing method according to claim 15, wherein the divided data generating module, if a length of a side of the pattern segment after being divided will be equal to or smaller than a predetermined length, does not divide the pattern segment.

22. A stencil mask layout pattern data division processing method according to claim 15, wherein the divided data generating module, if a length of the layout pattern segment is equal to or larger than a predetermined length, divides the pattern segment at a predetermined position irrespective of whether there is a recess corner or not.

23. A stencil mask layout pattern data division processing method according to claim 15, wherein the divided data generating module, if a foot of the perpendicular is positioned on the already cut-off side, does not cut the pattern segment along the perpendicular.

24. A stencil mask layout pattern data division processing method according to claim 15, wherein the divided data generating module, if two pieces of layout pattern segments adjacent to each other belong to the same complementary mask, subdivides one layout pattern segment into a plurality of layout pattern segments, and the complementary mask data generating module allocates the subdivided layout pattern segments such that the subdivided layout pattern segment, adjacent to the other layout pattern segment, among the plurality of subdivided layout pattern segments belongs to other complementary mask.

25. A stencil mask layout pattern data division processing method according to claim 15, wherein the divided data generating module generates the plural pieces of divided layout pattern segment data by dividing in the plurality of different directions the layout pattern data to meet dividing conditions stored in a dividing condition storage module.

26. A stencil mask layout pattern data division processing method according to claim 25, wherein the dividing condition setting module sets the dividing conditions in the dividing condition storage module.

27. A program, wherein a computer is made to function as:
a layout pattern data reading module for reading layout pattern data of a stencil mask from a layout pattern data storage module stored with the layout pattern data; and
a complementary mask data generating module for generating plural pieces of divided layout pattern segment data by dividing in the plurality of different directions the layout pattern data read by the layout pattern data reading module, generating plural pieces of complementary mask data by allocating the plural pieces of divided layout pattern segment data to plural pieces of complementary mask data, and storing the complementary mask data in the complementary mask data storage module.

28. A program according to claim 27, wherein the computer is made to function so that:
the complementary mask data generating module has a function as a divided data generating module for generating plural pieces of divided layout pattern segment data by dividing in a plurality of different directions the layout pattern data; and
the complementary mask data generating module stores a divided data storage module with the plural pieces of divided layout pattern segment data generated by the divided data generating module, and generates the complementary mask data by allocating the pattern data stored in the divided data storage module to plural pieces of complementary mask data.

29. A program according to claim 28, wherein the computer is made to function so that the divided data generating module divides the layout pattern segment along the shortest perpendicular extending to an adjacent side from a recess corner of the layout pattern data.

30. A program according to claim 29, wherein the computer is made to function so that the divided data generating module, if a plurality of shortest perpendiculars exist, divides the layout pattern segment to form the longest minor side among a plurality of sides extended between feet of the perpendiculars and a plurality of apexes sandwiching the feet interposed therebetween.

31. A program according to claim 30, wherein the computer is made to function so that the divided data generating module, if a plurality of longest minor sides exist, divides the layout pattern segment to form the longest major side among a plurality of sides extended between feet of the perpendiculars and a plurality of apexes sandwiching the feet interposed therebetween.

32. A program according to claim 29, wherein the computer is made to function so that the divided data generating module, if a plurality of shortest perpendiculars exist, divides the layout pattern segment to form the longest major side among a plurality of sides extended between feet of the perpendiculars and a plurality of apexes sandwiching the feet interposed therebetween.

33. A program according to claim 32, wherein the computer is made to function so that the divided data generating module, if a plurality of longest major sides exist, divides the layout pattern segment to form the longest minor side among a plurality of sides extended between feet of the perpendiculars and a plurality of apexes sandwiching the feet interposed therebetween.

34. A program according to claim 28, wherein the computer is made to function so that the divided data generating module, if a length of a side of the pattern segment after being divided will be equal to or smaller than a predetermined length, does not divide the pattern segment.

35. A program according to claim 28, wherein the computer is made to function so that the divided data generating module, if a length of the layout pattern segment is equal to or larger than a predetermined length, divides the pattern segment at a predetermined position irrespective of whether there is a recess corner or not.

36. A program according to claim 28, wherein the computer is made to function so that the divided data generating module, if a foot of the perpendicular is positioned on the already cut-off side, does not cut the pattern segment along the perpendicular.

37. A program according to claim 28, wherein the computer is made to function so that the divided data generating module, if two pieces of layout pattern segments adjacent to each other belong to the same complementary mask, subdivides one layout pattern segment into a plurality of layout pattern segments, and so that the complementary mask data generating module allocates the subdivided layout pattern segments such that the subdivided layout pattern segment, adjacent to the other layout pattern segment, among the plurality of subdivided layout pattern segments belongs to other complementary mask.

38. A program according to claim 28, wherein the computer is made to function so that the divided data generating module generates the plural pieces of divided layout pattern segment data by dividing in the plurality of different directions the layout pattern data to meet dividing conditions stored beforehand in the dividing condition storage module.

39. A program according to claim 38, wherein the computer is made to function further as a dividing condition setting module for setting the dividing conditions in the dividing condition storage module.
